(19) United States
(12) Patent Application Publication
(10) Pub. No.: US 2011/0204918 A1
(43) Pub. Date: Aug. 25, 2011

(54) DELAY SIMULATION SYSTEM, DELAY SIMULATION METHOD, PLD MAPPING SYSTEM, PLD MAPPING METHOD, AND SEMICONDUCTOR INTEGRATED CIRCUIT

(75) Inventor: Naoki NOJIRI, Osaka (JP)

(73) Assignee: PANASONIC CORPORATION, Osaka (JP)

(21) Appl. No.: 13/101,629

(22) Filed: May 5, 2011

Related U.S. Application Data
(63) Continuation of application No. PCT/JP2009/002171, filed on May 18, 2009.

(30) Foreign Application Priority Data
Nov. 6, 2008 (JP) 2008-285671

(51) Int. Cl. H03K 19/177; G06F 9/455

(52) U.S. Cl. 326/39; 716/108

(57) ABSTRACT

A delay simulation system comprises an input unit configured to input a netlist, a library, and information including load capacitances; and a simulation unit; the library defines a plurality of distortion patterns of input waveforms of the cells and defines delay values in correspondence with the plurality of distortion patterns of the input waveforms, slopes of the input waveforms, and the load capacitances; and the simulating unit is configured to calculate the delay time in such a manner that the simulating unit selects a distortion pattern of an input waveform according to a logic state of the cell, obtains a slope of the input waveform based on a load capacitance, and obtains a delay value corresponding to the distortion pattern of the input waveform, the slope of the input waveform and the load capacitance, from the library.

This is a continuation application under 35U.S.C. 111(a) of pending prior International application No. PCT/JP2009/002171, filed on May 18, 2009. The disclosure of Japanese Patent Application No. 2008-285671 filed on Nov. 6, 2008 including specification, drawings and claims is incorporated here in by reference in its entirety.

### BACKGROUND OF THE INVENTION

1. Field of the Invention

The present invention relates to a delay simulation system and a delay simulation method for a semiconductor integrated circuit comprising a plurality of cells connected to each other, and a mapping system, a mapping method and a semiconductor integrated circuit using the delay simulation system and the delay simulation method.

2. Description of the Related Art

When a semiconductor integrated circuit is designed, a delay simulation is conducted for the designed semiconductor integrated circuit, a maximum operation frequency which is a highest frequency with which the semiconductor integrate circuit is operative is derived based on a result of the simulation, and a performance of a product is decided based on the maximum operation frequency. To meet requirements of the performance, it is essential that a delay simulation for analyzing a delay characteristic of a circuit at a high speed and with high accuracy be conducted as well as designing of the circuit so that it is operative at a high speed. This is because, if delay calculation accuracy is low, it becomes necessary to add a delay calculation error due to the low accuracy to a delay time preliminarily as a margin, which degrades the performance of the semiconductor integrated circuit. If the delay simulation has high accuracy but requires a very long time, the delay simulation will not end within a realistic time in the case of a large-scale circuit.

In a cell-basis design in which cells are interconnected to form a circuit, delay time generated in signal paths including various paths is analyzed at a high speed using a library describing characteristics of the cells. The library contains various information of the respective cells. Delay characteristics of the cells are modeled and registered in the library. A delay simulation system is capable of deriving a delay time in a delay path with a plurality of cells connected to each other thereon, by referring to the delay characteristics of the cells registered in the library.

Conventionally, there is known a model expressing the delay characteristic of the cell by using two parameters which are a rising time and a falling time of an input waveform and a load capacitance. A delay table of this delay mode is shown in FIG. 15. FIG. 15 is a delay table in which a vertical axis indicates a slew rate which is the rising time and the falling time of the input waveform and a horizontal axis indicates the load capacitance with respect to the output. The delay time generated in a delay path with a plurality of cells connected to each other thereon is derived in such a manner that a delay value of each individual cell is obtained by extracting from the delay table a delay value corresponding to a rising time and a falling time of a waveform input to each individual cell and a load capacitance driven by each individual cell (or by providing approximation to attain a proper value), and these delay values are summed up.

However, the conventional library has a drawback that the waveform defining the rising time and the falling time of the input waveform is limited to that in a case where an ideal capacitance is driven.

As a solution to this, Japanese Laid-Open Patent Application Publication No. 2002-215710 discloses a delay analysis method in which a circuit is divided in a portion where a significant delay calculation error is not generated even when using an approximate waveform and dynamic timing analysis is conducted. Japanese Laid-Open Patent Application Publication No. Hei. 10-105581 discloses a delay analysis method in which a delay value is defined by a function of parameters.

### SUMMARY OF THE INVENTION

However, in the delay analysis method for conducting the circuit-divided dynamic timing analysis, if a circuit configuration is complicated or the kinds of them increases, the analysis requires a considerable time and the dynamic timing analysis requires a very long analysis time as compared to the delay analysis method which refers to the above mentioned table.

In the delay analysis method in which the delay value is defined by a function of parameters, it is difficult to express a waveform distortion as a function of the parameters because it is difficult to express the waveform distortion by numeric values, and further, difficulty arises in a case where the plurality of cells affect each other.

The present invention is developed in view of the above stated circumstances, and an object of the present invention is to provide a delay simulation system and a delay simulation method which are capable of conducting a high-speed and highly-accurate delay simulation in view of a distortion of a waveform generated by connecting a plurality of cells to each other, and a mapping system and a semiconductor integrated circuit using the delay simulation system and the delay simulation method.

To achieve the above objective, a delay simulation system according to an aspect of the present invention, comprises an input unit configured to input a netlist including a plurality of cells connected to each other as instances, a library defining delay values of the plurality of cells, and information including load capacitances driven by the cells; and a simulation unit configured to calculate a delay time of a signal path formed by connecting the plurality of cells to each other, based on the load capacitances with reference to the library; the library defining a plurality of distortion patterns of input waveforms of the cells and defining delay values in correspondence with the plurality of distortion patterns of the input waveforms, slopes of the input waveforms, and the load capacitances; and the simulating unit being configured to calculate the delay time in such a manner that the simulating unit selects a distortion pattern of an input waveform according to a logic state of a cell, obtains a slope of the input waveform based on a load capacitance, and obtains a delay value corresponding to the distortion pattern of the input waveform, the slope of the input waveform and the load capacitance, from the library.

In accordance with this configuration, the library defines a plurality of distortion patterns indicating how the input waveforms of the cells are distorted. The simulation unit identifies and selects a distortion pattern of an input waveform corresponding to a logic state of the cell from among the plurality of distortion patterns defined in the library. The library defines the delay values in correspondence with the distortion patterns of the input waveforms, the slopes of the input waveforms, and the load capacitances. The simulation unit obtains the slope of the input waveform based on the load capacitance, identifies and obtains a delay value corresponding to the distortion pattern of the input waveform, the slope of the input waveform and the load capacitance which are obtained as described above, from among the delay values defined in the library, and calculates the delay time of the signal path formed by connecting the plurality of cells to each other, using the delay value. Therefore, highly-accurate delay simulation is conducted considering the distortion of the waveform generated by connecting the plurality of cells to each other. In delay calculation considering the distortion of the waveform, how the input waveforms of cells are distorted is patterned, as the distortion patterns, according to the logic states of the cells preliminarily, and the distortion pattern is selected from among the distortion patterns, thereby obtaining the delay value. Thus, the delay simulation is conducted at a high speed.

The netlist may include a drive cell which is disposed as the instance and outputs to a first net a signal (logic signal) indicating a predetermined logic according to a signal input to the drive cell, and a cell instance connected to the first net and fed with the logic signal; the simulation unit may include; a logic state determination unit configured to determine the signal path formed by connecting the plurality of cells to each other and determine a logic state of the cell instance; a waveform select unit configured to select a distortion pattern of an input waveform of each cell in the library based on the logic state determined by the logic state determination unit; and a delay processor unit configured to calculate the delay time in such a manner that the delay processor unit obtains the slope of the input waveform based on the load capacitance, and obtains the delay value corresponding to the distortion pattern of the input waveform selected by the waveform select unit, the slope of the input waveform, and the load capacitance, from the library.

The cell instance may include at least a transfer gate.

The cell instance may be connected to a second net, one end of the transfer gate may be connected to the first net, and the other end of the transfer gate may be connected to the second net.

The library may define input capacitances of the cell instance in a logic state at which the cell instance is in ON-state, respectively, in correspondence with a plurality of intervals in a period of a voltage transition from one logic level to the other logic level of the logic signal; and the waveform select unit may select a distortion pattern of an input waveform at the first net based on the input capacitance in the library.

The waveform select unit may obtain an input capacitance corresponding to an interval from the library according to the logic state of the cell instance, obtains the distortion of the input waveform at the first net based on the obtained input capacitance, and may select the distortion pattern of the input waveform based on the obtained distortion of the input waveform.

The library may include a logic state-distortion pattern conversion table defining distortion patterns of input waveforms at the first net in correspondence with logic states of the cell instances; and the waveform may select unit may select the distortion pattern of the input waveform at the first net from the logic state-distortion pattern conversion table in the library, according to the logic state of the cell instance determined by the logic state determination unit.

The library may include a load capacitance basis logic state-distortion pattern conversion table defining distortion patterns of input waveforms at the first net in correspondence with logic states of the cell instances and load capacitances driven by the cell instances; and the waveform select unit may select the distortion pattern of the input waveform at the first net from the load capacitance basis logic state-distortion pattern conversion table in the library, according to the logic state of the cell instance determined by the logic state determination unit and the load capacitance driven by the cell instance.

The first net may be connected with a plurality of cell instances; the logic state-distortion pattern conversion table may define the distortion patterns of the input waveforms at the first net in correspondence with combinations of the logic states of the plurality of cell instances; and the waveform select unit may select the distortion pattern of the input waveform at the first net from the logic state-distortion pattern conversion table in the library, according to a combination of the logic states of the plurality of cell instances determined by the logic state determination unit.

The first net may be connected with a plurality of cell instances; the library may include a load capacitance basis logic state-distortion pattern conversion table defining the distortion patterns of the input waveforms at the first net in correspondence with combinations of logic states of the plurality of cell instances and a plurality of load capacitances driven by the plurality of cell instances, respectively; and the waveform select unit may select the distortion pattern of the input waveform at the first net from the load capacitance basis logic state-distortion pattern conversion table in the library, according to the combination of logic states of the plurality of cell instances determined by the logic state determination unit, and a combination of the plurality of load capacitances driven by the plurality of cell instances.

The simulation unit may obtain, as the slope of the input waveform, a slope of a portion of a waveform input to the cell, the portion being an initial portion in a period of transition from one logic level to the other logic level.

A PLD mapping system according to another aspect of the present invention is configured to calculate delay using aforesaid delay simulation system, perform mapping of a logic circuit to a PLD circuit based on a result of calculation of the delay and output resulting mapping information to the PLD circuit.

A semiconductor integrated circuit according to a further aspect of the present invention, comprises a PLD circuit programmed based on mapping information obtained by calculation of delay using the above delay simulation system.

A delay simulation method according to a further aspect of the present invention, comprises a step of obtaining a netlist including a plurality of cells connected to each other as instances, a library defining delay values of the plurality of cells, and information including load capacitances driven by the cells; and a simulation step of calculating a delay time of a signal path formed by connecting the plurality of cells to each other, based on the load capacitances with reference to the library; the library defining a plurality of distortion patterns of input waveforms of the cells and defining delay values in correspondence with the plurality of distortion patterns of the input waveforms, slopes of the input waveforms, and the load capacitances; and the simulating step includes calculating the delay time in such a manner that a distortion pattern of an input waveform is selected according to a logic state of a cell, a slope of the input waveform is obtained based on a load capacitance, and a delay value corresponding to the distortion pattern of the input waveform, the slope of the input waveform and the load capacitance, is obtained from the library.

In accordance with this method, like the delay simulation mentioned above, high-speed and highly-accurate delay simulation can be carried out considering the distortion of the waveform generated by connecting the plurality of cells to each other.

The netlist may include a drive cell which is disposed as the instance and outputs to a first net, a signal (logic signal) indicating a predetermined logic according to a signal input to the drive cell, and a cell instance connected to the first net and fed with the logic signal; the simulation step may include; a logic state determination step of determining the signal path formed by connecting the plurality of cells to each other and determining a logic state of the cell instance; a waveform selecting step of selecting a distortion pattern of an input waveform of each cell in the library based on the logic state determined in the logic state determination step; and a delay calculating step of calculating the delay time in such a manner that the slope of the input waveform is obtained based on a load capacitance, and the delay value corresponding to the distortion pattern of the input waveform selected in the waveform selecting step, the slope of the input waveform, and the load capacitance, is obtained from the library.

The cell instance may include at least a transfer gate.

The cell instance may be connected to a second net, one end of the transfer gate may be connected to the first net, and the other end of the transfer gate may be connected to the second net.

The library may define input capacitances of the cell instance in a logic state at which the cell instance is in ON-state, respectively, in correspondence with a plurality of intervals in a period of a voltage transition from one logic level to the other logic level of the logic signal; and the waveform selecting step may include selecting a distortion pattern of an input waveform at the first net based on the input capacitance in the library.

The waveform selecting step may include obtaining an input capacitance corresponding to an interval from the library according to the logic state of the cell instance, obtaining the distortion of the input waveform at the first net based on the obtained input capacitance, and selecting the distortion pattern of the input waveform based on the obtained distortion of the input waveform.

The library may include a logic state-distortion pattern conversion table defining the distortion patterns of the input waveform at the first net in correspondence with the logic states of the cell instances; and the waveform selecting step may include selecting the distortion pattern of the input waveform at the first net from the logic state-distortion pattern conversion table in the library, according to the logic state of the cell instance determined in the logic state determination step.

The library may include a load capacitance basis logic state-distortion pattern conversion table defining the distortion patterns of the input waveforms at the first net in correspondence with logic states of cell instances and load capacitances driven by the plurality of cell instances, respectively; and the waveform selecting step may include selecting the distortion pattern of the input waveform at the first net from the load capacitance basis logic state-distortion pattern conversion table in the library, according to the logic state of the cell instance determined in the logic state determination step and the load capacitance driven by the cell instance.

The first net may be connected with a plurality of cell instances; the logic state-distortion pattern conversion table may define the distortion patterns of the input waveforms at the first net in correspondence with combinations of logic states of the plurality of cell instances; the waveform selecting step may include selecting the distortion pattern of the input waveform at the first net from the logic state-distortion pattern conversion table in the library, according to a combination of logic states of the plurality of cell instances determined in the logic state determination step.

The first net may be connected with a plurality of cell instances; the library may include a load capacitance basis logic state-distortion pattern conversion table defining distortion patterns of input waveforms at the first net in correspondence with combinations of logic states of the plurality of cell instances and a plurality of load capacitances driven by the plurality of cell instances, respectively; and the waveform selecting step may include selecting the distortion pattern of the input waveform at the first net from the load capacitance basis logic state-distortion pattern conversion table in the library, according to a combination of logic states of the plurality of cell instances determined in the logic state determination step, and a combination of the plurality of load capacitances driven by the plurality of cell instances.

The simulation step may include obtaining, as the slope of the input waveform, a slope of a portion of a waveform input to the cell, the portion being an initial portion in a period of transition from one logic level to the other logic level.

A PLD mapping method of the present invention, comprises calculating delay using the above delay simulation method; performing mapping of a logic circuit to a PLD circuit based on a result of calculation of the delay; and outputting resulting mapping information to the PLD circuit.

The above and further objects and features of the invention will more fully be apparent from the following detailed description with reference to the accompanying drawings.

### BRIEF DESCRIPTION OF THE DRAWINGS

FIG. 1 is a functional block diagram showing a configuration of a simulation system according to Embodiment 1 of the present invention.

FIG. 2 is a flowchart showing a delay simulation operation of the simulation system of FIG. 1.

FIG. 3 is a circuit diagram showing a cell constituted by a buffer which is one of cells defined as a library.

FIG. 4 is a circuit diagram showing a circuit in which a load capacitance as a parasitic element is connected to the cell constituted by the buffer.

FIG. 5A is a waveform diagram showing input waveforms having distortions and shows types of the waveforms.

FIG. 5B is a waveform diagram showing input waveforms having distortions and shows slopes of the waveforms of one type.

FIG. 6 is a view showing an exemplary delay table defined in a library of a buffer BUF.

FIG. 7 is a circuit diagram showing a circuit including transfer gates which are an example of a netlist.

FIG. 8A is a circuit diagram showing a detailed circuit of a cell registered in the library and shows a detailed circuit having a buffer function.

FIG. 8B is a circuit diagram showing a detailed circuit of a cell registered in the library and shows a detailed circuit of a cell having a transfer gate.

FIG. 9 is a circuit diagram showing an electric equivalent circuit in a state where the transfer gate is ON.

FIG. 10 is a view showing a waveform select table defining types of the input waveforms in correspondence with ON/OFF states of transfer gates of FIG. 7.

FIG. 11 is a view showing an exemplary input voltage interval basis input capacitance table used to select a waveform according to Embodiment 2 of the present invention.

FIG. 12 is a view showing an exemplary load capacitance basis waveform select table used to select a waveform according to Embodiment 3 of the present invention.

FIG. 13 is a circuit diagram showing a configuration of a semiconductor integrated circuit according to Embodiment 4 of the present invention.

FIG. 14 is a flowchart showing a procedure of PLD mapping, for creating and outputting mapping information for changing a function of a PLD circuit of FIG. 13.

FIG. 15 is a view showing a conventional delay table defining delay values in correspondence with combinations of load capacitances and slew rates.

### DETAILED DESCRIPTION OF THE PREFERRED EMBODIMENTS

Hereinafter, preferred embodiments of the present invention will be described with reference to the drawings. Throughout the drawings, the same or corresponding constituents and components are designated by the same reference symbols and will not be described repetitively.

### Embodiment 1

[Configuration]

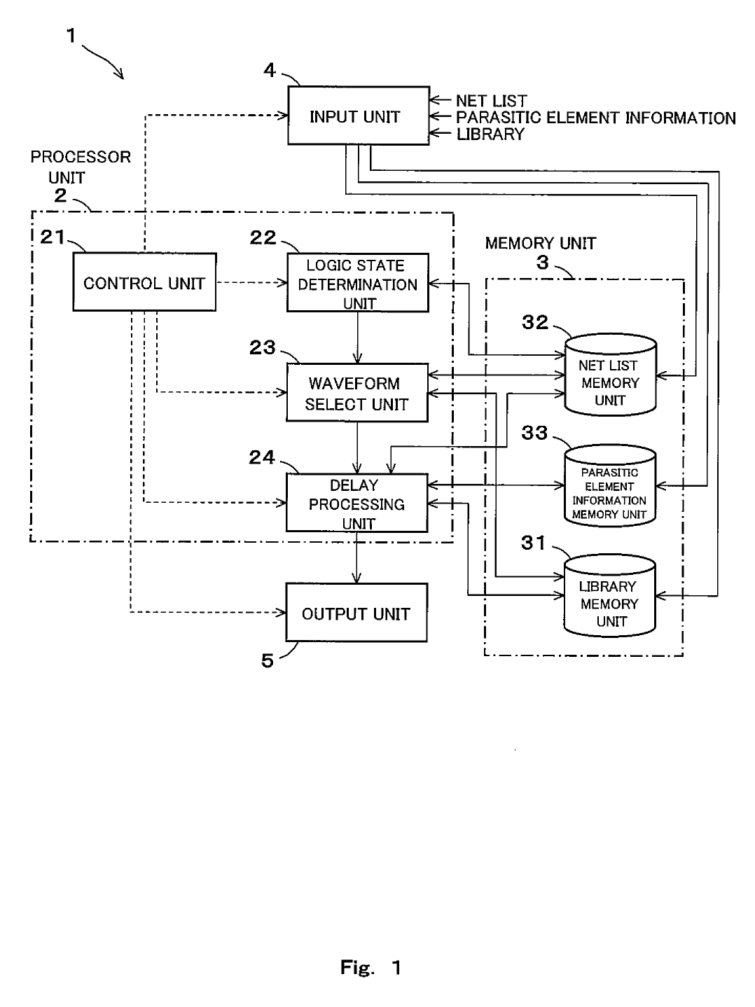

FIG. 1 is a functional block diagram showing a configuration of a simulation system according to Embodiment 1 of the present invention.

Turning now to FIG. 1, a simulation system 1 of this embodiment includes a processor unit 2, a memory unit 3, an input unit 4, and an output unit 5. The processor unit 2 includes a control unit 21, a logic state determination unit 22, a waveform select unit 23, and a delay processing unit 24. The logic state determination unit 22, the waveform select unit 23, and the delay processing unit 24 constitute a simulation unit. The memory unit 3 includes a library memory unit 31, a netlist memory unit 32 and a parasitic element information memory unit 33.

Hardware of the simulation system 1 is constituted by, for example, a computer and its peripheral devices. A CPU of the computer reads out a predetermined simulation program stored in an internal memory (ROM, RAM, hard disc, etc.) of the computer and executes the program. In this way, the computer operates as a simulation system.

FIG. 1 is a functional block diagram showing a function of the simulation system implemented by the predetermined simulation program. In the hardware of the simulation system 1, the processor unit 2 is constituted by the CPU of the computer, and the memory unit 3 is constituted by an internal memory of the computer. The input unit 4 is constituted by an input device such as a key board or a mouse, or an input/output device such as an external memory (flexible disc drive, CD drive, etc.) or a connection device (e.g., modem) for providing communication with a data communication line. The output unit 5 is constituted by an output device such as a display or a printer, or an input/output device such as the external memory or the connection device for providing communication with the data communication line.

The input unit 4 is capable of inputting a library, a netlist, and parasitic element information. To be specific, in the input unit 4, for example, a library input image, a netlist input image, and a parasitic element information input image are displayed on the display device, and the library, the netlist, and the parasitic element information which are stored in a storage medium are input via the external memory by operating the input device such as the mouse. As defined herein, the library refers to information describing delay characteristics of cells. A specific content of the library will be described in detail later. The netlist is information describing a connection relation of cells in a delay analysis target circuit. To be more specific, the netlist is data of information about connection between terminals in an electronic circuit. The netlist is used to design, for example, wiring on a printed board. In a field of electronic circuits, connection of signal lines connecting terminals to each other and connection between the terminals is called a net. In an electronic design automated system such as EDA (Electronic Design Automation) tool, transmission and reception of electronic circuit data is performed efficiently using the netlist. The parasitic element information is information relating to parasitic elements including load capacitances driven by the cells described in the netlist. The library, the netlist, and the parasitic element information are created preliminarily in the form of data files, and are stored and preserved in a memory such as a storage medium.

The library memory unit 31, the netlist memory unit 32 and the parasitic element information memory unit 33 are configured to store the library, the netlist, and the parasitic element information which are input by the input unit 4, respectively.

The logic state determination unit 22 is configured to read out a netlist from the netlist memory unit 32 and decide a signal path which is a delay time analysis target in a circuit corresponding to the netlist read out and logic states of cell instances which affect a delay time.

The waveform select unit 23 is configured to read out a waveform select table from the library stored in the library memory unit 31 and select a type of a waveform (hereinafter sometimes referred to as input waveform) of an input signal of the net of the signal path which is the analysis target based on the logic states decided by the logic state determination unit 22, from the waveform select table read out. The type of the input waveform will be described in detail later. When selecting the type of the input waveform, the waveform select unit 23 reads out the netlist from the netlist memory unit 32 and uses the associated circuit information.

The delay processing unit 24 is configured to obtain (extract) a delay value of a cell instance which is an analysis target based on the parasitic element information stored in the parasitic element information memory unit 32 and the input waveform type selected in the library memory unit 23, with reference to the library stored in the library memory unit 31. The delay processing unit 24 reads out the netlist from the netlist memory unit 32 and uses the associated circuit information when obtaining (extracting) the delay value.

The output unit 5 is configured to output the delay value obtained in the delay processing unit 24. To be specific, for example, the output unit 5 displays the obtained delay value on the display or prints out the obtained delay value. Or, the output unit 5 stores the obtained delay value in a storage medium in an external memory, or transmits the obtained delay value to another computer via the connection device connected with the data communication line.

The control unit 21 is configured to control the operation of the input unit 4, the operation of the logic state determination unit 22, the operation of the waveform select unit 23, the operation of the delay processing unit 24, and the operation of the output unit 5.

[Operation]

Next, a delay simulation operation of the delay simulation system configured as described above will be described. The delay simulation operation of the delay simulation system is a delay simulation method according to this embodiment.

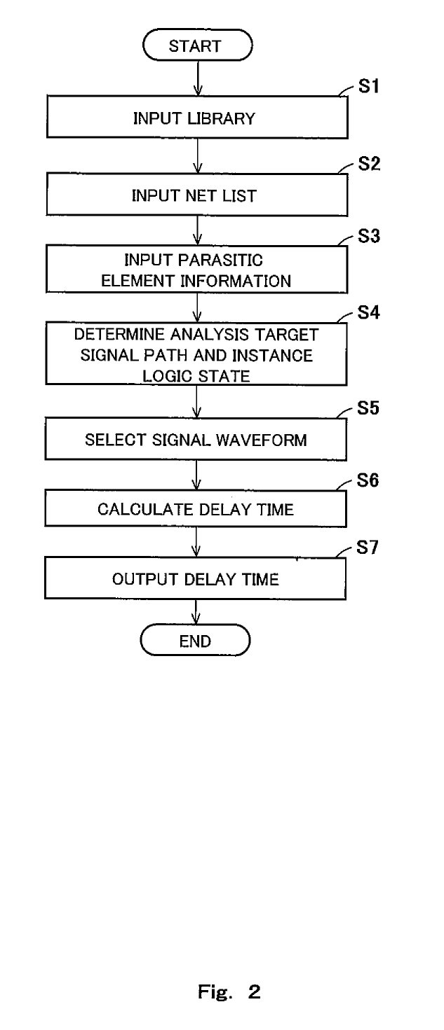

FIG. 2 is a flowchart showing the delay simulation operation of the simulation system of FIG. 1.

The delay simulation operation is implemented by executing the above described predetermined simulation program by the CPU. Hereinafter, it is supposed that the delay simulation operation is executed along the functional block diagram of FIG. 1 under control of the control unit 21.

With reference to FIG. 2, the control unit 21 causes the input unit 4 to input the library (step S1).

To be specific, for example, in the input unit 4, the library input image is displayed on the display device, and the library stored in the form of data file in the storage medium is input via the external memory by operating the input device such as the mouse. The input library is stored in the library memory unit 31.

Hereinafter, the library will be described specifically with regard to, for example, a cell having a buffer function, which is one of cells defined as the library.

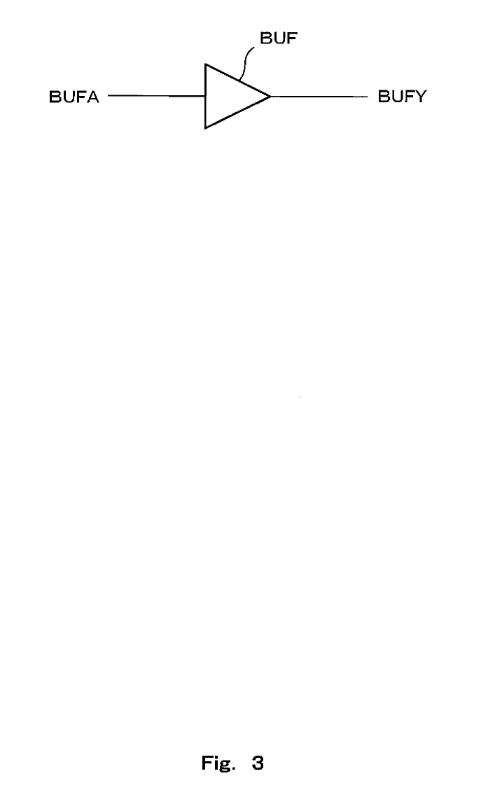

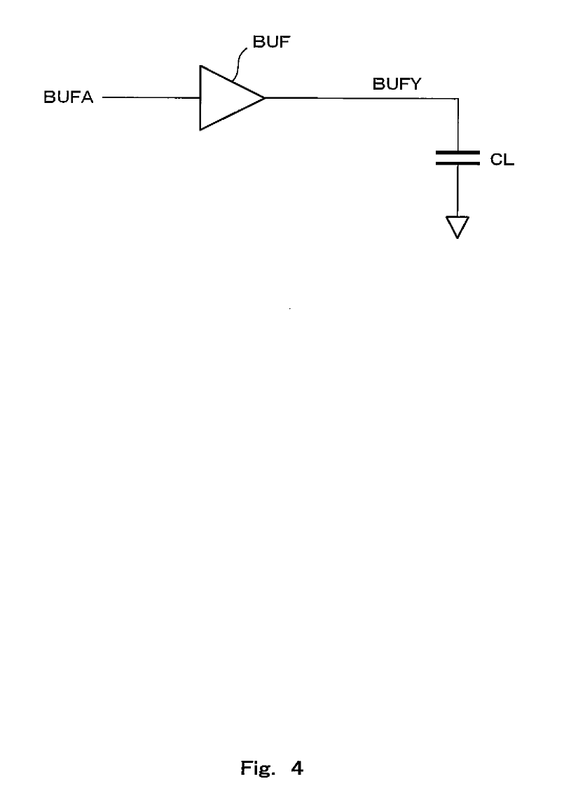

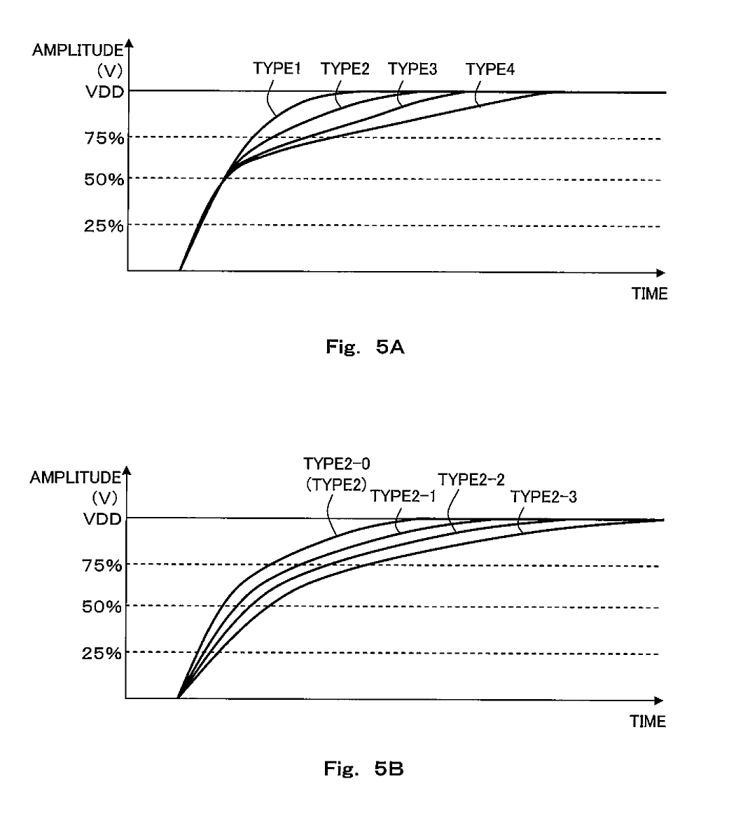

FIG. 3 is a circuit diagram showing a cell constituted by a buffer which is one of the cells defined as the library. FIG. 4 is a circuit diagram showing a circuit in which a load capacitance as a parasitic element is connected to the cell constituted by the buffer. FIG. 5A is a waveform diagram showing input waveforms having distortions and shows types of the waveform. FIG. 5B is a waveform diagram showing input waveforms having distortions and shows slopes of the waveforms of one type. In FIGS. 5A and 5B, a horizontal axis indicates a time and a vertical axis indicates an amplitude (voltage) of the input signal. A scale of the vertical axis indicates a percentage with respect to a positive power supply voltage VDD.

In FIG. 3, the buffer BUF indicates the cell instance, BUFA indicates an input terminal of the buffer BUF, and BUFY indicates an output terminal of the buffer BUF. In delay analysis, as shown in FIG. 4, a load capacitance CL is connected to the output terminal BUFY. That is, the buffer BUF is analyzed as driving the load capacitance CL. An input signal is input to the input terminal BUFA. This input signal is a signal (logic signal) that transitions between two logic levels which are Low level and High level. To carry out delay analysis at a high speed and with high accuracy, in a conventional method, the input signal is defined as an input signal having a determined waveform having one slope. On the other hand, in the present invention, to achieve delay analysis with higher accuracy, as shown in FIG. 5A, a plurality of input waveforms having distortions different from each other are patterned and defined in the library, in view of a waveform distortion generated by connecting the plurality of cells to each other. Hereinafter, a pattern indicating how the input waveform is distorted (configuration of distortion) is referred to as a type (distortion pattern) of the input waveform. In FIG. 5A, an input waveform of TYPE 1 is an input waveform in a case where the buffer drives only an ideal load capacitance. An input waveform of TYPE 2 is an input waveform having a greater distortion than the input waveform of TYPE 1, because of a certain circuit factor. An input waveform of TYPE 3 and an input waveform of TYPE 4 are input waveforms having greater distortions than the input waveform of TYPE 2, because of a certain circuit factor. As shown in FIG. 5B, as the input waveforms of the respective types, a plurality of input waveforms having slew rates (slopes of input waveforms) different from each other are defined in the library. As should be appreciated, in the present invention, the input waveforms are identified by the types (distortion patterns) and the slew rates (slopes of waveforms). Therefore, identifying an input waveform means identifying one or both of its type and its slew rate.

FIG. 5B depicts four kinds of input waveforms having different slew rates, in the input waveform of TYPE 2. When the slew rate is defined as a time for which the input signal transitions in an interval from 0% to 25% of the power supply voltage VDD, in the example shown in FIG. 5B, an input waveform of TYPE2-0 has the same shape as the input waveform of TYPE 2. In other words, the input waveform of TYPE2-0 is an input waveform having a distortion of TYPE 2 having a shortest slew rate (having a steepest rising). An input waveform of TYPE2-1, an input waveform of TYPE2-2, and an input waveform of TYPE2-3 are input waveforms obtained by multiplying the input waveform of TYPE2-0 by coefficients with respect to a time axis, respectively. The input waveform of TYPE2-1 is an input waveform having a distortion of TYPE 2 and having a longer slew rate (having a gentler rising) than the input waveform of TYPE2-0. The input waveform of TYPE2-2 and the input waveform of TYPE2-3 are input waveforms each having a distortion of TYPE 2 and having a longer slew rate (having a gentler rising) than the input waveform of TYPE2-1.

Although FIG. 5B depicts only the input waveforms having different slew rates in the input waveform of TYPE2, the same applies to input waveforms having different slew rates in the input waveforms of another types. Although FIGS. 5A and 5B depict only rising waveforms that transition from Low level to High level, falling waveforms that transition from High level to low level are identical to the rising waveforms except for a direction in which a signal (voltage) transitions.

Next, the delay table defined in the library of the buffer BUF will be described.

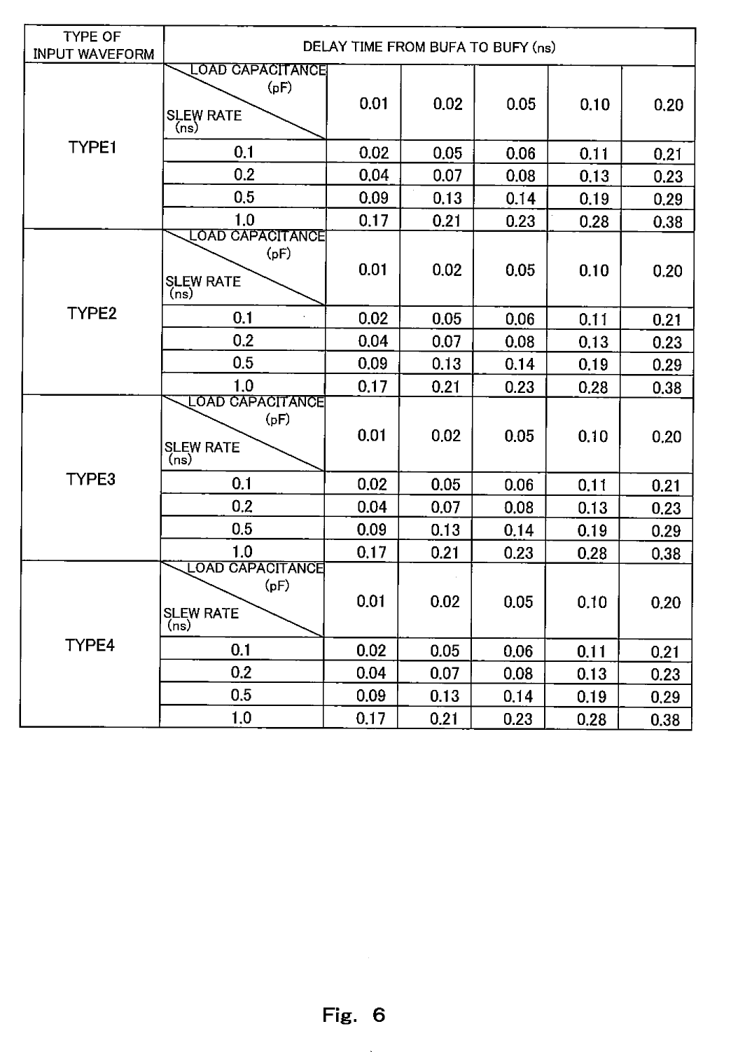

FIG. 6 is a view showing an exemplary delay table defined in the library of the buffer BUF. As shown in FIG. 6, the delay table contains delay times from an input terminal of a cell to an input terminal of the cell, i.e., delay times (unit: ns) from the input terminal BUFA to the output buffer BUFY in the case of the buffer BUF in correspondence with combinations of types of input waveforms, the slew rates of the input waveforms and the load capacitances with respect to the outputs. The slew rates of the input waveforms correspond to the input waveforms shown for different slew rates in FIG. 5B, respectively. For example, the slew rates “0.1 ns”, “0.2 ns”, “0.5 ns”, and “1.0 ns” of the slew rates of TYPE2 in the delay table of FIG. 6, correspond to the input waveforms of “TYPE2-0”, “TYPE2-1”, “TYPE2-2”, and “TYPE2-3”, respectively, of FIG. 5B. The same applies to the input waveforms of another types. For this reason, if the type of the input waveform at the input terminal BUFA, the slew rate of the input waveform, and the load capacitance CL are determined, then the delay time of the buffer BUF in a path from the input terminal BUFA to the output buffer BUFY is obtained (extracted), with reference to the delay table shown in FIG. 6. The form of the delay table is not limited to that shown in FIG. 6. Although FIG. 6 depicts that the delay time corresponds to a change in the slew rate of the input waveform and a change in the load capacitance, for each type of the input waveform, the delay time may correspond to a change in the slew rate of the input waveform and a change in the type of the input waveform for each load capacitance, or otherwise the delay time may correspond to a change in the load capacitance and a change in the type of the input waveform, for each slew rate of the input waveform. In a case where the cell instance is a circuit element other than the buffer, the delay table is defined in the same manner.

Turning back to FIG. 2, the control unit 21 causes the input unit 4 to input the netlist (step S2).

To be specific, in the input unit 4, for example, the netlist input image is displayed on the display device, and the netlist stored in the form of data file in the storage medium is input via the external memory by operating the input device such as the mouse. The input netlist is stored in the netlist memory unit 32.

Now, a specific example of the netlist will be described. Hereinafter, description will be given in conjunction with the specific example of the netlist.

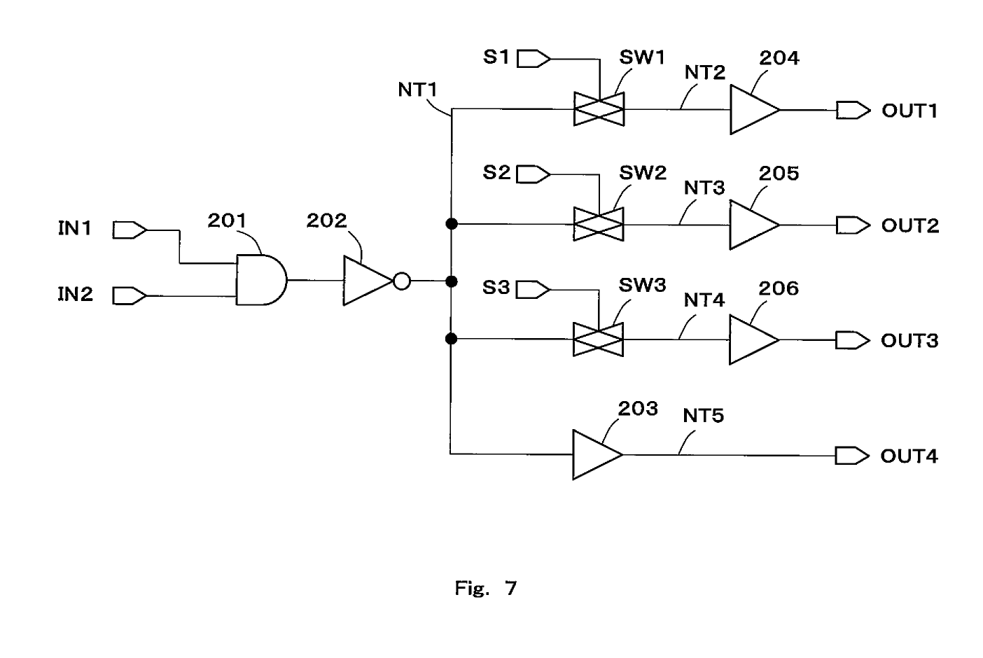

FIG. 7 is a circuit diagram showing a circuit including transfer gates, which is an example of the netlist. As shown in FIG. 7, an input terminal IN1 and an input terminal IN2 are connected to two input terminals of an AND gate 201, respectively. An output terminal of the AND gate 201 is connected to an input terminal of an inverter 202. An output terminal of the inverter 202 is connected to input terminals of transfer gates SW1, SW2, and SW3, and to an input terminal of the buffer 203 via a net NT1 (first net). Output terminals of the transfer gates SW1, SW2, and SW3 are connected to input terminals of buffers 204, 205 and 206, respectively, via nets NT2, NT3, and NT4 (second nets), respectively. Output terminals of the buffers 204, 205, 206, and 203 are connected to output terminals OUT1, OUT2, OUT3, and OUT4, respectively. ON/OFF control terminals of the transfer gates SW1, SW2, and SW3 are connected to control terminals S1, S2 and S3, respectively. In this circuit, an input signal indicating a logic is input to the input terminal IN1 and to the input terminal IN2. The AND gate 201 and the inverter 202 output a signal (logic signal) indicating the logic of this input signal to the net NT1.

The AND gate 201, the inverter 201, the transfer gates SW1, SW2, and SW3, and the buffers 203, 204, 205, and 206 are instances (cell instances) defined as cells. The individual cell instances are interconnected via the nets. The inverter 202 is a drive cell for driving the net NT1.

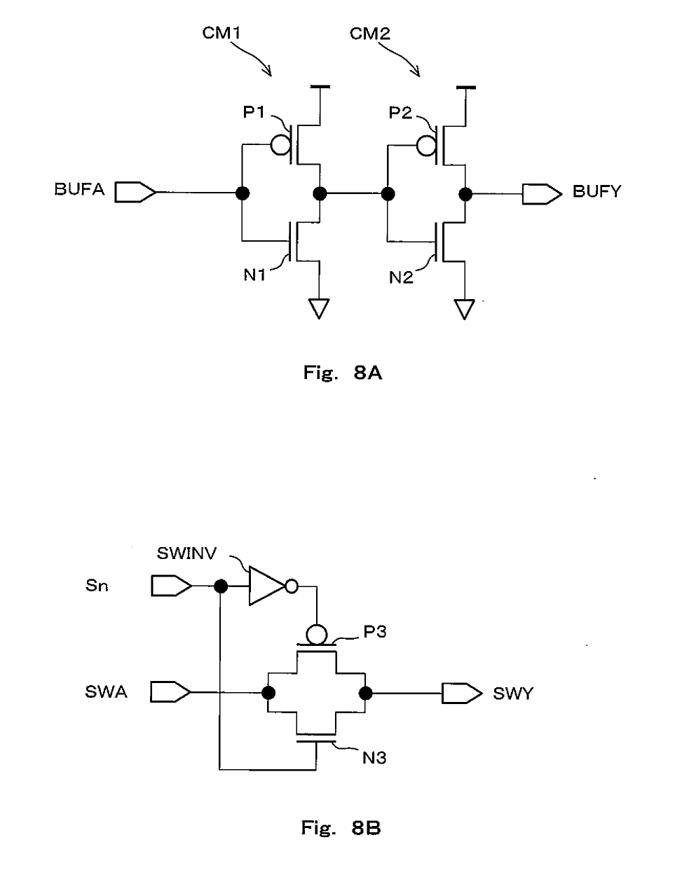

FIG. 8A is a circuit diagram showing a detailed circuit of a cell registered in the library and shows a detailed circuit of the cell having a buffer function. FIG. 8B is a circuit diagram showing a detailed circuit of a cell registered in the library and shows a detailed circuit of the cell having a transfer gate.

For example, in a case where an input terminal is connected to only a gate in a cell constituted by a CMOS circuit, typically, the input terminal is defined in the library as a circuit having only a capacitance. For example, as shown in FIG. 8A, the buffer 203 is constituted by two CMOS circuits CM1 and CM2 connected in two stages. The first CMOS circuit CM1 includes a P-type MOS transistor P1 and a N-type MOS transistor N1 connected in series with each other. Gates of the MOS transistors P1 and N1 are connected to the input terminal BUFA, while sources of the MOS transistors P1 and N1 are connected to an electric power source and a ground, respectively. A second CMOS circuit CM2 includes a P-type MOS transistor P2 and a N-type MOS transistor N2 connected in series with each other. Gates of the MOS transistors P2 and N2 are connected to drains of the P-type MOS transistor P1 and the N-type MOS transistor N1 in the first CMOS circuit CM1. Sources of the MOS transistors P2 and N2 are connected to an electric power source and a ground, respectively. Drains of the MOS transistors P2 and N2 are connected to the output terminal BUFY.

In this circuit, the gate of the P-type transistor P1 and the gate of the N-type transistor N1 are electrically disconnected from the output terminal BUFY, and a load capacitance of the output terminal BUFY affects the input terminal BUFA very little. For this reason, a load capacitance of the input terminal BUFA is easily defined as an input capacitance CBUFA from the input terminal BUFA to the ground. The same occurs in the AND gate 201 and the inverter 202.

The transfer gate is a circuit in which an input terminal is electrically connected to and disconnected from an output terminal. Therefore, unlike the buffer, a load capacitance of the input terminal cannot be defined as the input capacitance.

For example, each of the transfer gates SW1, SW2 and SW3 is constituted by the circuit shown in FIG. 8B. As shown in FIG. 8B, each of the transfer gates SW1, SW2 and SW3 includes a P-type MOS transistor P3 and a N-type MOS transistor N3 connected in parallel with each other. One end (source) of the P-type MOS transistor P3 and one end (source) of the N-type MOS transistor N3 are connected to an input terminal SWA. The other end (drain) of the P-type MOS transistor P3 and the other end (drain) of the N-type MOS transistor N3 are connected to an output terminal SWY. A gate of the N-type MOS transistor N3 is connected to a control terminal Sn. A gate of the P-type MOS transistor P3 is connected to the control terminal Sn via an inverter SWINV. In this configuration, a control signal input to the control terminal Sn and inverted in logic by the inverter SWINV is input to the gate of the P-type MOS transistor P3.

In this circuit, when the control terminal Sn is at High level, the P-type MOS transistor P3 and the N-type MOS transistor N3 are ON and the input terminal SWA is electrically connected to the output terminal SWY, i.e., the transfer gate is ON. On the other hand, when the control terminal Sn is at Low level, the P-type MOS transistor P3 and the N-type MOS transistor N3 are OFF and the input terminal SWA is electrically disconnected from the output terminal SWY, i.e., the transfer gate is OFF.

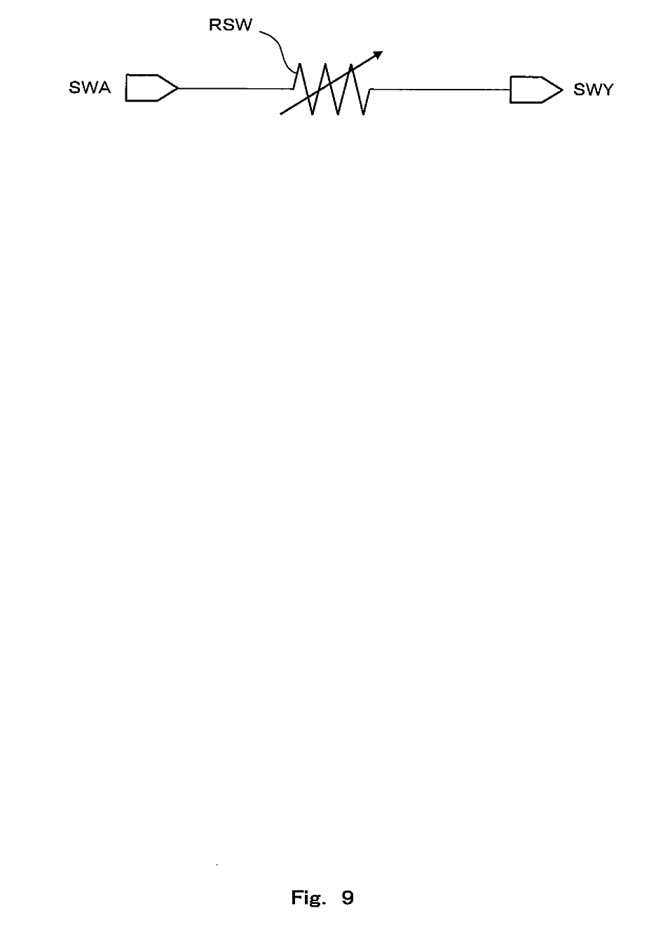

FIG. 9 is a circuit diagram showing an electric equivalent circuit in a state where the transfer gate is ON. As shown in FIG. 9, the transfer gate in ON-state is electrically expressed as a variable resistance RSW. The variable resistance RSW has a series resultant resistance (hereinafter referred to as a resultant ON-resistance) of ON-resistance of the P-type MOS transistor P3 and ON-resistance of the N-type MOS transistor N3. Since ON-resistance of the transistor changes depending on electric potentials of its drain and source, the resultant ON-resistance changes depending on the electric potential at the input terminal SWA and the electric potential at the output terminal SWY. Therefore, if the resultant ON-resistance is modeled as a simple resistance having only one resistance value, then modeling accuracy decreases significantly.

The transfer gate has a characteristic in which, when an input signal transitions from Low level to High level, ON-resistance is higher in an interval at Low level side of the input signal, while when an input signal transitions from High level to Low level, ON-resistance is higher in an interval at High level side of the input signal. A waveform distortion which is caused by the fact that circuit elements located at both sides of the transfer gate affect each other via the transfer gate is less when the ON-resistance of the transfer gate is higher. For this reason, as shown in FIG. 5A, in a rising waveform, a waveform distortion is less in an interval at Low level side relative to a medium electric potential. In a falling waveform, a waveform distortion is less in an interval at High level side relative to a medium electric potential, although not shown. Therefore, it is most desirable that these portions be defined as the slew rates of the input waveforms. In this embodiment, the slew rates of the input waveforms are defined as such.

Turning back to FIG. 2, the control unit 21 causes the input unit 4 to input the parasitic element information (step S3).

To be specific, in the input unit 4, for example, the parasitic element information input image is displayed on the display device, and the parasitic element information stored in the form of data file in the storage medium is input via the external memory by operating the input device such as the mouse. The input parasitic element information is stored in the parasitic element information memory unit 33.

Then, the control unit 21 causes the logic state determination unit 22 to read out the netlist from the netlist memory unit 32, and decides a signal path which is a delay time analysis target and logic states of cell instances which affect the delay time, in a circuit corresponding to the netlist (step S4).

Hereinafter, this will be described in conjunction with the above described specific example of the netlist.

Initially, the logic state determination unit 22 decides logic states of the control terminals S1, S2 and S3 of the transfer gates SW1, SW2, and SW3 for which a delay simulation is conducted. In this manner, whether each of the transfer gates SW1, SW2, and SW3 is in ON-state or in OFF-state is decided.

Then, the control unit 21 causes the waveform select unit 23 to select a type of an input waveform of a net of the signal path which is the analysis target based on the logic states decided in the logic state determination unit 22 (step S5).

To be specific, the waveform select unit 23 reads in the waveform select table in the library stored in the library memory unit 31.

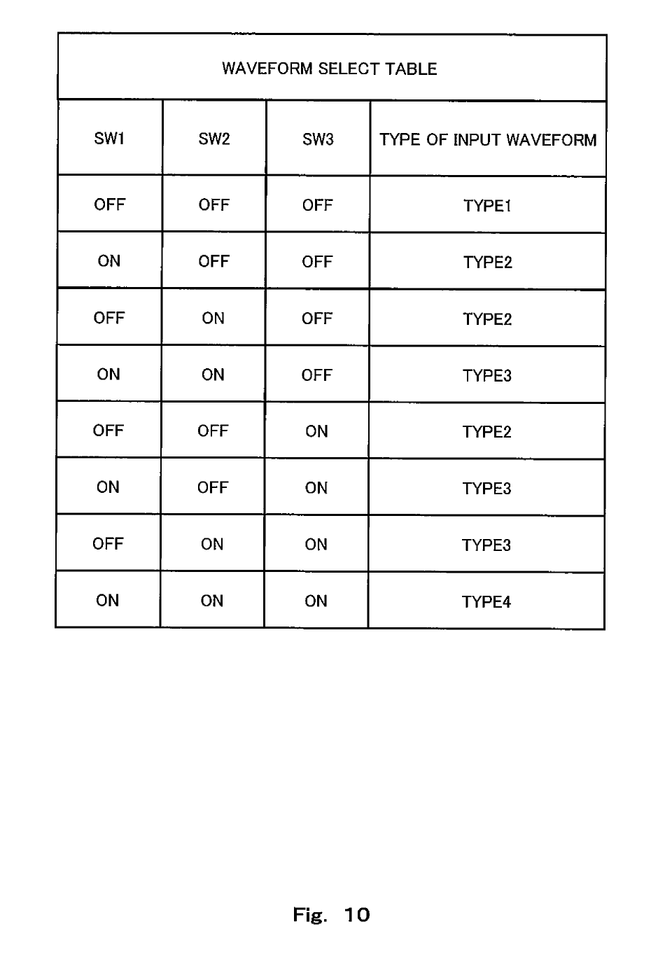

FIG. 10 is a view showing the waveform select table defining types of the input waveforms in correspondence with ON/OFF states of transfer gates of FIG. 7.

Referring to FIG. 10, according to this waveform select table (logic state-distortion pattern conversion table), types of the input waveforms at the net NT1 are defined depending on whether the transfer gates SW1, SW2, and SW3 are in ON-state or OFF-state. This allows the waveform select unit 23 to identify the type of the input waveform at the net NT1 corresponding to the ON/OFF states of the transfer gates SW1, SW2, and SW3, with reference to the waveform select table. For example, when all of the transfer gates SW1, SW2, and SW3 are OFF, a load capacitance driven by the inverter 202 is minimum, and only an input capacitance of the buffer 203 defined as the cell having an ideal capacitance of an input is driven by the inverter 202. In this case, therefore, as a type of the waveform at the net NT1, a type with a smallest distortion in a case where only the ideal capacitance is driven, i.e., TYPE 1 is defined.

For example, when only the transfer gate SW1, among the transfer gates SW1, SW2, and SW3, is ON, there is a need for the inverter 202 to drive the input capacitance of the buffer 204 via the transfer gate SW1, in addition to the input capacitance of the buffer 204. Since the input capacitance of the buffer 204 is connected to the net NT1 via the ON-resistance of the transfer gate SW1, the input waveform at the net NT1 is distorted by the ON-resistance of the transfer gate SW1 and the input capacitance of the buffer 204 which is a load with respect to the output of the transfer gate SW1. Therefore, in the present case, as a type of the input waveform at the net NT1, a type with a second smallest distortion, i.e., TYPE2 is defined.

When a plurality of transfer gates are ON, the input waveform at the net NT1 has a more complex distortion, because of the fact that ON-resistances of the respective transfer gates and the corresponding load capacitances affect each other. This distortion increases as the transfer gates in ON-state increase in number. Therefore, the types of the input waveforms at the net NT1 in a case where the plurality of transfer gates are ON, are defined as TYPE 2, TYPE3 and TYPE4 in an increasing order of the number of the transfer gates in ON-state.

In the above described configuration, the waveform select unit 23 selects the type of the input waveform at the net NT1 according to the ON/OFF states of the transfer gates SW1 to SW3, with reference to the waveform select table of FIG. 10. Since the types of the input waveforms are defined in the waveform select table preliminarily in this way, the type of the input waveform can be obtained easily and at a high speed.

Then, the control unit 21 causes the delay processing unit 24 to obtain a parasitic element (in this embodiment, load capacitance) and a slew rate corresponding to the net of the signal path which is the analysis target, based on the parasitic element information stored in the parasitic element information memory unit 32, and to obtain a delay value of a cell instance which is an analysis target, based on the parasitic element, the slew rate, and the type of the input waveform selected in the waveform select unit 23, with reference to the library stored in the library memory unit 31 (step S6).

To be specific, the delay processing unit 24 initially obtains the load capacitance as the parasitic element connected to the net of the signal path which is the analysis target, based on the parasitic element information stored in the parasitic element information memory unit 32. Then, the delay processing unit 24 obtains the slew rate of the input waveform at the net NT1 based on the load capacitance, and the output characteristic of the cell instance (see FIG. 7) defined in the library. It should be noted that since the slew rate of the input waveform including a waveform distortion is substantially the same as the slew rate of the ideal input waveform including no waveform distortion, the slew rate of the input waveform at the net NT1 can be derived in a well-known method used in the conventional technique. Therefore, explanation thereof is omitted. Then, the delay processing unit 24 refers to the delay table (see FIG. 6) in the library stored in the library memory unit 31, and obtains, from the delay table, a delay value which corresponds to a combination of the type of the input waveform, the slew rate and the load capacitance, which have been obtained in the above explained procedure. In the above described manner, it is possible to obtain the delay values of the respective cell instances in the circuit including transfer gates as an example of the netlist of FIG. 7, and hence the delay value of the signal path from the input terminals IN1 and IN2 to the output terminals OUT1 to OUT4.

As described above, delay analysis is carried out.

Then, the control unit 21 causes the output unit 5 to output the obtained delay value (step S7).

[Advantage]

In accordance with the above embodiment as described above, for the cell with its input being electrically connected to its output, like the transfer gate, high-speed and highly-accurate delay simulation can be carried out using the delay table defining the delay values in correspondence with the distortion patterns (types) of the input waveforms, the slew rates (slopes of waveforms) of the input waveforms, and the load capacitances, and the waveform select table. In other words, it is possible to carry out high-speed and highly-accurate delay simulation in view of the waveform distortion generated by connecting the plurality of cells to each other. Therefore, great advantages are achieved by applying this embodiment to a delay simulation system and a delay simulation method for a circuit including transfer gates.

Furthermore, in accordance with this embodiment, even for a circuit in which cell instances interfere with each other via a net, an input waveform generated by the interference can be obtained easily merely by referring to a table. As a result, a configuration of the delay simulation system can be simplified, and the delay simulation can be performed at a high speed.

[Modification Example]

Although the configuration in which the plurality of transfer gates are connected to the net NT1 has been described, similar advantages are achieved in a configuration in which a single transfer gate is connected to the net NT1. Although the transfer gates SW1, SW2, and SW3 are controlled in accordance with signals input through the control terminals S1, S2 and S3, respectively, in the above configuration, control memories for controlling ON and OFF of the transfer gates SW1, SW2, and SW3 may be incorporated into the transfer gates SW1, SW2, and SW3, respectively. In that case, of course, the input waveform may be selected according to logic states of the control memories.

The waveform select table may be created and defined preliminarily for each net within a netlist read-in, or may be defined as being grouped according to a state of a circuit corresponding to the netlist.

Alternatively, only typical input waveforms may be listed in the delay table, and numeric values of the parameters of the input waveforms in the delay table may be interpolated, thereby attaining delay values with higher accuracy.

Although each transfer gate is configured to include both of the P-type MOS transistor P3 and the N-type MOS transistor N3 for the purpose of easier explanation, it may consist of the P-type MOS transistor P3 or the N-type MOS transistor N3. In a further alternative, each transfer gate may include a transistor of another type such as a bipolar transistor.

### Embodiment 2

In Embodiment 1, the waveform is selected using the waveform select table. In embodiment 2, the waveform is selected without using the waveform select table.

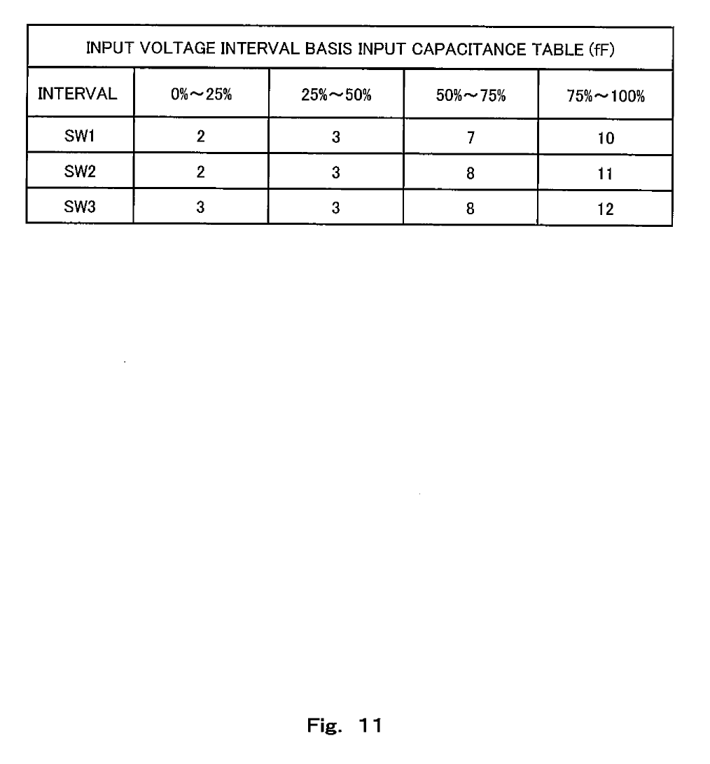

FIG. 11 is a view showing an exemplary input voltage interval basis input capacitance table used to select a waveform according to Embodiment 2 of the present invention.

Referring to FIG. 11, the input voltage interval basis input capacitance table is created in such a manner that a waveform (input waveform) of a voltage signal input to each transfer gate is divided into a plurality of intervals (in this embodiment, four intervals) in a period of transition from one logic level (in this embodiment, Low level) to the other logic level (in this embodiment, High level), and an apparent input capacitance (unit fF) of the transfer gate is defined for each interval. An apparent input capacitance of the transfer gate in a logic state at which the transfer gate is OFF is constant and is not depicted in FIG. 11. Therefore, only input voltage interval basis input capacitances in logic states at which the transfer gates are ON are depicted in FIG. 11. Substantially, input voltage interval basis input capacitances are depicted according to logic states, respectively in FIG. 11.

As described above, the ON-resistance of the transfer gate changes according to a voltage applied. Therefore, in a case where the cell instance is a transfer gate, an apparent input capacitance when viewed from an input terminal changes as the input waveform transitions from one logic level to the other logic level. For example, in a rising period during which an electric potential (voltage) at the input terminal is transitioning from Low level to High level, when the input electric potential is at Low level side in a former half part of the transition, a low current flows because of a high ON-resistance of the transfer gate, and therefore an apparent input capacitance is small. On the other hand, when the input electric potential is at High level side in a latter half part of the transition, a high current flows because of a low ON-resistance of the transfer gate, and therefore an apparent input capacitance is large. Accordingly, when the cell instance is the transfer gate, the input waveform to the transfer gate can be identified with higher accuracy by using a plurality of input capacitances corresponding to a plurality of voltage intervals in the period of transition of the input waveform, instead of a single fixed input capacitance.

To be specific, in this embodiment, the input voltage interval basis input capacitance table of FIG. 11 is defined in the library. The waveform select unit 23 reads out the input voltage interval basis input capacitance table from the library memory unit 31, calculates an apparent resultant input capacitance when viewed from the input terminal according to ON/OFF of the transfer gates SW1, SW2, and SW3, and identifies the input waveform, based on this. Then, the waveform select unit 23 selects as the identified input waveform type, a type of an input waveform closest to the identified input waveform, from among the input waveforms of TYPE1 to TYPES.

The delay processing unit 24 obtains the slew rate at the net NT1 based on the resultant input capacitance in the interval of “0% to 25%” of the input voltage interval basis input capacitance table. Then, the delay processing unit 24 obtains (extracts) a delay value corresponding to a combination of the type of the input waveform identified as described above, the above slew rate, and the above load capacitance, from the delay table. In other respect, Embodiment 2 is identical to Embodiment 1.

In accordance with this embodiment, an optimal input waveform can be selected according to ON/OFF states of the transfer gates SW1, SW2, and SW3, based on the input capacitances in respective input voltage intervals of the transfer gates SW1, SW2, and SW3, in addition to the input capacitance CBUFA of the buffer 203 defined as a single input capacitance. In addition, unlike SPICE simulation, simulation which is low in abstraction level and is time consuming, or a complex function are unnecessary.

Although the input voltage interval basis input capacitances are defined without depending on the slew rates of the input waveforms in the table of FIG. 11, they may defined depending on the slew rates. This makes it possible to select the input waveform with higher accuracy.

Although the configuration in which the plurality of transfer gates are connected to the net NT1 has been described, similar advantages are achieved in a configuration in which a single transfer gate is connected to the net NT1.

### Embodiment 3

In Embodiment 3 of the present invention, a waveform select table which is different from that of Embodiment 1 is used.

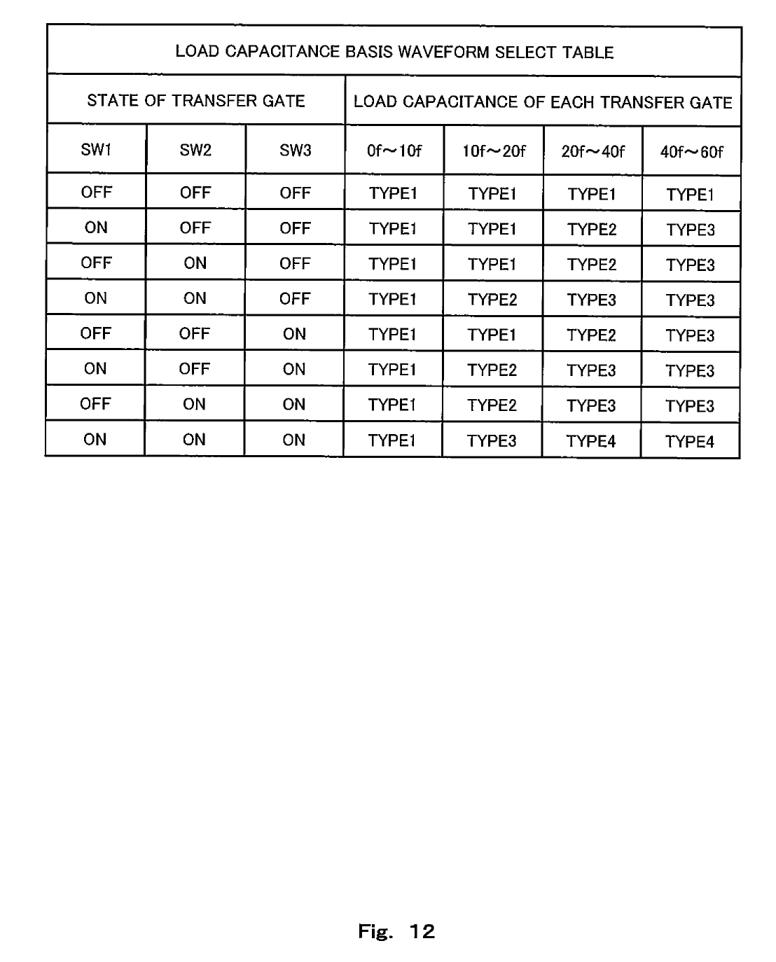

FIG. 12 is a view showing an exemplary load capacitance basis waveform select table used to select a waveform according to Embodiment 3 of the present invention.

Referring to FIG. 12, the load capacitance basis waveform select table (load capacitance basis logic state-distortion pattern conversion table) defines types of input waveforms at the net NT1 in correspondence with combinations of the ON/OFF states of the transfer gates SW1, SW2, and SW3 and the load capacitances of the respective transfer gates SW1, SW2, and SW3.

In this embodiment, the load capacitance basis waveform select table is described in the library instead of the waveform select table (see FIG. 10) of Embodiment 1. The waveform select unit 33 reads out the load capacitance basis waveform select table from the library memory unit 31, and reads out load capacitances in a circuit corresponding to a netlist from the parasitic element information memory unit 33. The waveform select unit 33 selects the type of the input waveform corresponding to a combination of the ON/OFF states of the transfer gates SW1, SW2, and SW3 and the load capacitances of the respective transfer gates SW1, SW2, and SW3, from the load capacitance basis waveform select table. In other respect, embodiment 3 is identical to Embodiment 1.

In accordance with this embodiment, even in a case where the load capacitances of the transfer gates are different, the type of the input waveform is selected by referring to the same table. Since the number of tables used to conduct the delay simulation is lessened, maintenance is performed more efficiently.

Although the load capacitance basis waveform select table of FIG. 12 defines the type of the input waveform on a load capacitance basis (for each load capacitance range) so as to be common to all of the transfer gates SW1, SW2, and SW3, it may define the type of the input waveform on a load capacitance basis in a different manner among the transfer gates SW1, SW2, and SW3. This makes it possible to apply the waveform select table of this embodiment to a general circuit.

### Embodiment 4

In Embodiment 4 of the present invention, the delay simulation systems (delay simulation methods) of Embodiment 1 to Embodiment 3 are applied to a PLD circuit.

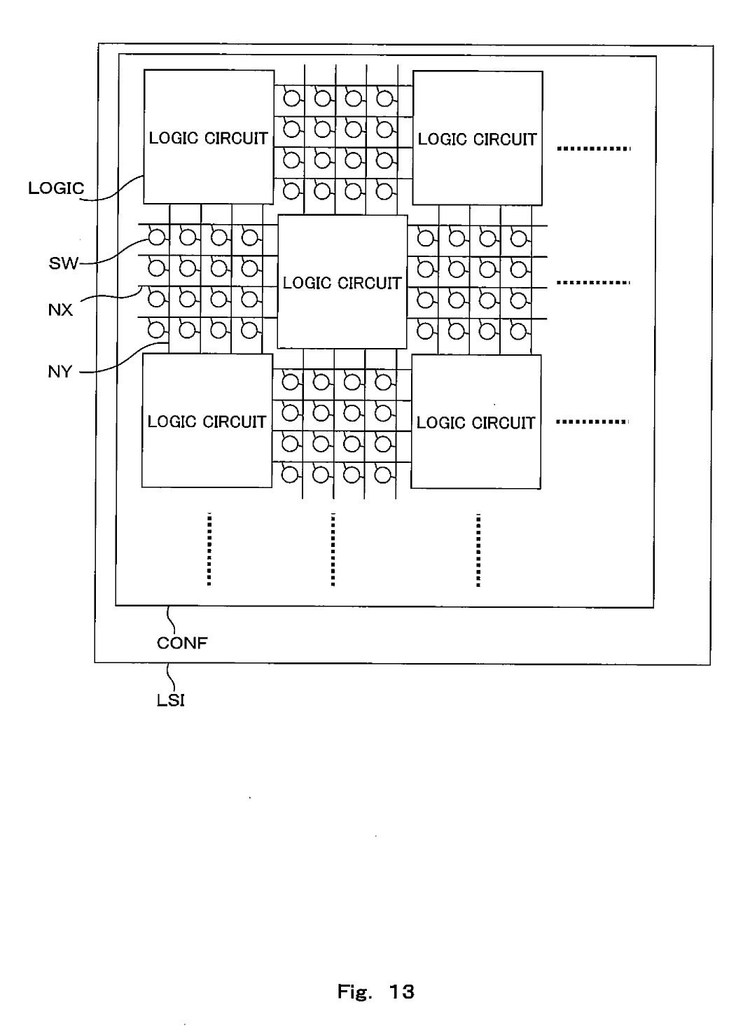

FIG. 13 is a circuit diagram showing a configuration of a semiconductor integrated circuit according to Embodiment 4 of the present invention.

Referring to FIG. 13, a PLD (programmable circuit) CONF is incorporated into a semiconductor integrated circuit LSI of this embodiment. The PLD circuit CONF has a general configuration. The PLD circuit CONF is configured to have a desired function. The PLD circuit CONF includes programmable logic circuits LOGIC which can be modified into circuits having various functions, wires NY connecting the logic circuits LOGIC to each other in a longitudinal direction, wires NX connecting the logic circuits LOGIC to each other in a lateral direction, and switches SW connecting and disconnecting the wires NY and the wires NX. These circuit elements are disposed in array in the PLD circuit CONF. Each switch SW is constituted by a transfer gate and its ON/OFF operation is controlled by a configuration memory incorporated into the switch SW.

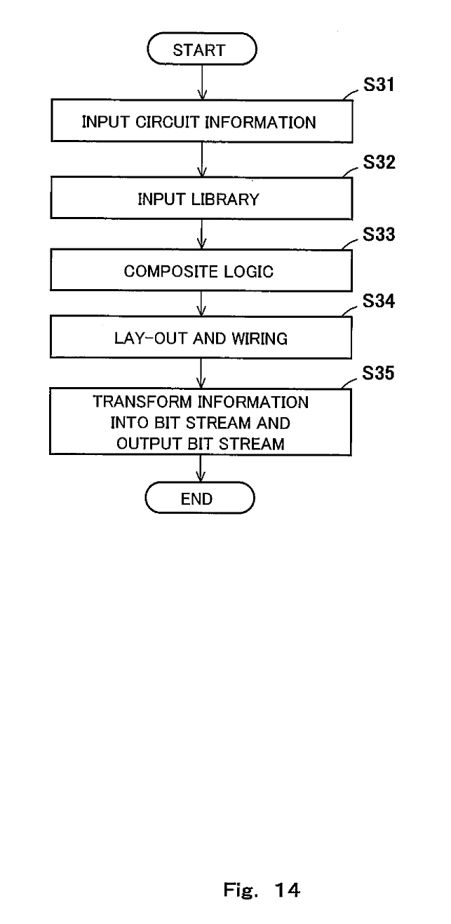

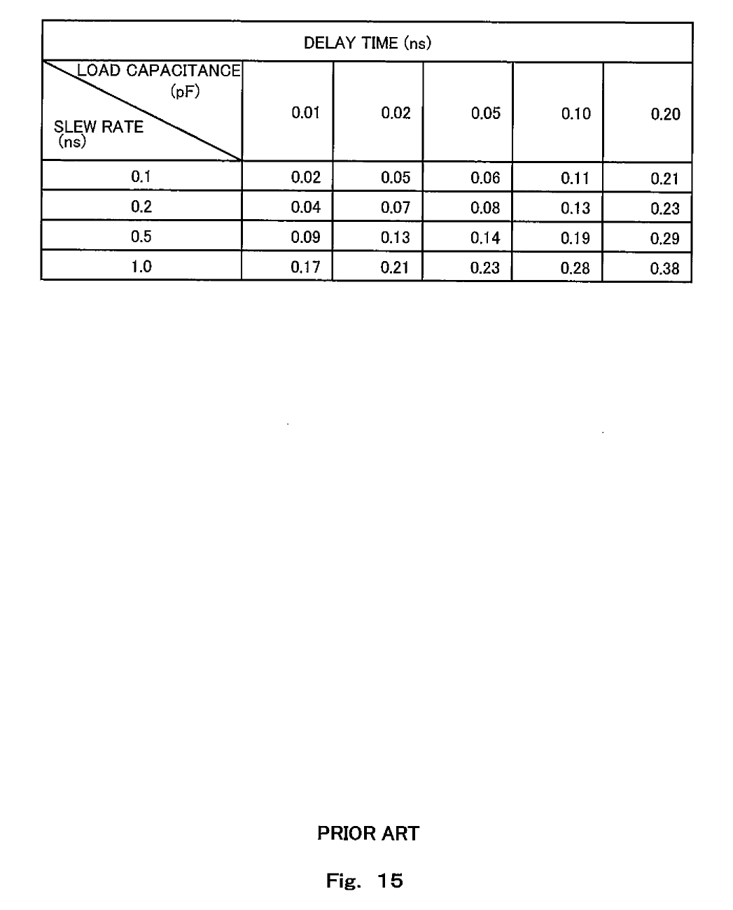

FIG. 14 is a flowchart showing a procedure of PLD mapping, for creating and outputting mapping information for modifying a function of the PLD circuit CONF. The PLD mapping is executed by a PLD mapping system (not shown).

Firstly, the PLD mapping system inputs (reads-in) circuit information to be mapped (step S31).

Then, the PLD mapping system inputs (reads-in) a library in which cells incorporated into the PLD circuit CONF are registered (step S32).

Then, the PLD mapping system converts the input circuit information into a circuit including only cells included in the PLD circuit CONF and defined as the library (step S33).

Then, the PLD mapping system performs mapping by laying out the converted circuit in the PLD circuit CONF and performing wiring (step S34). In this mapping, in this embodiment, delay calculation is performed and a maximum operation speed is obtained, using any one of the delay simulation systems (delay simulation methods) of Embodiment 1 to Embodiment 3.

Then, the PLD mapping system transforms the mapped mapping information into a bit stream which is data to be read-in by the PLD circuit CONY (step S35).

Thereafter, the data of the bit stream output from the PLD mapping system is stored in a configuration memory incorporated into the PLD circuit CONF. In the PLD circuit CONF so configured, the switch SW is controlled in accordance with the mapping information stored in the configuration memory incorporated thereinto, and the PLD circuit CONF is modified into a circuit having a desired function and operates as such. In the PLD circuit CONY, a value stored in the configuration memory is rewritten only in a configuration mode in which a function of the PLD circuit CONY is modified, and is not in an application mode in which the PLD circuit CONY operates as a circuit having a desired function. In the delay simulation systems (delay simulation methods) of Embodiment 1 to Embodiment 3, logics of the control terminals of the transfer gates are decided and delay calculation is performed. Therefore, it may be said that applying the delay calculation of Embodiment 1 to Embodiment 3 to the mapping in the PLD circuit CONF in which the logics of the control terminals of the transfer gates are invariable in the application mode is most desirable to the delay simulation systems (delay simulation methods) of Embodiment 1 to Embodiment 3. In addition, the PLD circuit CONF can be suitably programmed.

Numerous modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

A delay simulation system of the present invention is useful as a high-speed and high-definition delay simulation system or the like.

A delay simulation method of the present invention is useful as a high-speed and high-definition delay simulation method or the like.

A PLD mapping system and a PLD mapping method of the present invention are useful as a PLD mapping system, a PLD mapping method, or the like which are capable of mapping a PLD circuit suitably with respect to delay.

A semiconductor integrated circuit of the present invention is useful as a semiconductor integrated circuit or the like including a PLD circuit capable of suitably programming.

What is claimed is:

1. A delay simulation system comprising:
an input unit configured to input a netlist including a plurality of cells connected to each other as instances, a library defining delay values of the plurality of cells, and information including load capacitances driven by the cells; and
a simulation unit configured to calculate a delay time of a signal path formed by connecting the plurality of cells to each other, based on the load capacitances with reference to the library;
the library defining a plurality of distortion patterns of input waveforms of the cells and defining delay values in correspondence with the plurality of distortion patterns of the input waveforms, slopes of the input waveforms, and the load capacitances; and
the simulating unit being configured to calculate the delay time in such a manner that the simulating unit selects a distortion pattern of an input waveform according to a logic state of the cell, obtains a slope of the input waveform based on a load capacitance, and obtains a delay value corresponding to the distortion pattern of the input waveform, the slope of the input waveform and the load capacitance, from the library.

2. The delay simulation system according to claim 1, wherein
the netlist includes a drive cell which is disposed as the instance and outputs to a first net a signal (logic signal) indicating a predetermined logic according to a signal input to the drive cell, and a cell instance connected to the first net and fed with the logic signal;
the simulation unit includes;
a logic state determination unit configured to determine the signal path formed by connecting the plurality of cells to each other and determine a logic state of the cell instance;
a waveform select unit configured to select a distortion pattern of an input waveform of each cell in the library based on the logic state determined by the logic state determination unit; and
a delay processor unit configured to calculate the delay time in such a manner that the delay processor unit obtains the slope of the input waveform based on the load capacitance and obtains the delay value corresponding to the distortion pattern of the input waveform selected by the waveform select unit, the slope of the input waveform, and the load capacitance, from the library.

3. The delay simulation system according to claim 2, wherein
the cell instance includes at least a transfer gate.

4. The delay simulation system according to claim 3, wherein
the cell instance is connected to a second net, one end of the transfer gate is connected to the first net, and the other end of the transfer gate is connected to the second net.

5. The delay simulation system according to claim 4, wherein
the library defines input capacitances of the cell instance in a logic state at which the cell instance is in ON-state, respectively, in correspondence with a plurality of intervals in a period of a voltage transition from one logic level to the other logic level of the logic signal; and
the waveform select unit selects a distortion pattern of an input waveform at the first net based on the input capacitance in the library.

6. The delay simulation system according to claim 2, wherein the library defines input capacitances of the cell instance in a logic state at which the cell instance is in ON-state, respectively, in correspondence with a plurality of intervals in a period of a voltage transition from one logic level to the other logic level of the logic signal; and
the waveform select unit selects a distortion pattern of an input waveform at the first net based on the input capacitance in the library.

7. The delay simulation system according to claim 6, wherein
the waveform select unit obtains an input capacitance corresponding to an interval from the library according to the logic state of the cell instance, obtains the distortion of the input waveform at the first net based on the obtained input capacitance, and selects the distortion pattern of the input waveform based on the obtained distortion of the input waveform.

8. The delay simulation system according to claim 2, wherein
the library includes a logic state-distortion pattern conversion table defining distortion patterns of input waveforms at the first net in correspondence with logic states of the cell instances; and
the waveform select unit selects the distortion pattern of the input waveform at the first net from the logic state-distortion pattern conversion table in the library, according to the logic state of the cell instance determined by the logic state determination unit.

9. The delay simulation system according to claim 2, wherein
the library includes a load capacitance basis logic state-distortion pattern conversion table defining distortion patterns of input waveforms at the first net in correspondence with logic states of the cell instances and load capacitances driven by the cell instances; and
the waveform select unit selects the distortion pattern of the input waveform at the first net from the load capacitance basis logic state-distortion pattern conversion table in the library, according to the logic state of the cell instance determined by the logic state determination unit and the load capacitance driven by the cell instance.

10. The delay simulation system according to claim 8, wherein
the first net is connected with a plurality of cell instances;
the logic state-distortion pattern conversion table defines the distortion patterns of the input waveforms at the first net in correspondence with combinations of the logic states of the plurality of cell instances; and
the waveform select unit selects the distortion pattern of the input waveform at the first net from the logic state-distortion pattern conversion table in the library, according to a combination of the logic states of the plurality of cell instances determined by the logic state determination unit.

11. The delay simulation system according to claim 9, wherein
the first net is connected with a plurality of cell instances;
the library includes a load capacitance basis logic state-distortion pattern conversion table defining the distortion patterns of the input waveforms at the first net in correspondence with combinations of logic states of the plurality of cell instances and a plurality of load capacitances driven by the plurality of cell instances, respectively; and
the waveform select unit selects the distortion pattern of the input waveform at the first net from the load capacitance basis logic state-distortion pattern conversion table in the library, according to a combination of logic states of the plurality of cell instances determined by the logic state determination unit, and a combination of the plurality of load capacitances driven by the plurality of cell instances.

12. The delay simulation system according to claim 1, wherein
the simulation unit obtains, as the slope of the input waveform, a slope of a portion of a waveform input to the cell, the portion being an initial portion in a period of transition from one logic level to the other logic level.

13. A PLD mapping system configured to calculate delay using the delay simulation system as recited in claim 1, perform mapping of a logic circuit to a PLD circuit based on a result of calculation of the delay, and output resulting mapping information to the PLD circuit.

14. A semiconductor integrated circuit comprising a PLD circuit programmed based on mapping information obtained by calculation of delay using the delay simulation system as recited in claim 1.

15. A delay simulation method comprising:
a step of obtaining a netlist including a plurality of cells connected to each other as instances, a library defining delay values of the plurality of cells, and information including load capacitances driven by the cells; and
a simulation step of calculating a delay time of a signal path formed by connecting the plurality of cells to each other, based on the load capacitances with reference to the library;
the library defining a plurality of distortion patterns of input waveforms of the cells and defining delay values in correspondence with the plurality of distortion patterns of the input waveforms, slopes of the input waveforms, and the load capacitances; and
the simulating step includes calculating the delay time in such a manner that a distortion pattern of an input waveform is selected according to a logic state of a cell, a slope of the input waveform is obtained based on a load capacitance, and a delay value corresponding to the distortion pattern of the input waveform, the slope of the input waveform and the load capacitance, is obtained from the library.

16. The delay simulation method according to claim 15, wherein
the netlist includes a drive cell which is disposed as the instance and outputs to a first net, a signal (logic signal) indicating a predetermined logic according to a signal input to the drive cell, and a cell instance connected to the first net and fed with the logic signal;
the simulation step includes;
a logic state determination step of determining the signal path formed by connecting the plurality of cells to each other and determining a logic state of the cell instance;
a waveform selecting step of selecting a distortion pattern of an input waveform of each cell in the library based on the logic state determined in the logic state determination step; and
a delay calculating step of calculating the delay time in such a manner that a slope of the input waveform is obtained based on a load capacitance, and a delay value corresponding to the distortion pattern of the input waveform selected in the waveform selecting step, the slope of the input waveform, and the load capacitance, is obtained from the library.

17. The delay simulation method according to claim 16, wherein the cell instance includes at least a transfer gate.

18. The delay simulation method according to claim 17, wherein
the cell instance is connected to a second net, one end of the transfer gate is connected to the first net, and the other end of the transfer gate is connected to the second net.

19. The delay simulation method according to claim 18, wherein
the library defines input capacitances of the cell instance in a logic state at which the cell instance is in ON-state, respectively, in correspondence with a plurality of intervals in a period of a voltage transition from one logic level to the other logic level of the logic signal; and
the waveform selecting step includes selecting a distortion pattern of an input waveform at the first net based on the input capacitance in the library.

20. The delay simulation method according to claim 16, wherein
the library defines input capacitances of the cell instance in a logic state at which the cell instance is in ON-state, respectively, in correspondence with a plurality of intervals in a period of a voltage transition from one logic level to the other logic level of the logic signal; and
the waveform selecting step includes selecting a distortion pattern of an input waveform at the first net based on the input capacitance in the library.

21. The delay simulation method according to claim 20, wherein
the waveform selecting step includes obtaining an input capacitance corresponding to an interval from the library according to the logic state of the cell instance, obtaining the distortion of the input waveform at the first net based on the obtained input capacitance, and selecting the distortion pattern of the input waveform based on the obtained distortion of the input waveform.

22. The delay simulation method according to claim 16, wherein
the library includes a logic state-distortion pattern conversion table defining the distortion patterns of the input waveform at the first net in correspondence with the logic states of the cell instances; and
the waveform selecting step includes selecting the distortion pattern of the input waveform at the first net from the logic state-distortion pattern conversion table in the library, according to the logic state of the cell instance determined in the logic state determination step.

23. The delay simulation method according to claim 16, wherein
the library includes a load capacitance basis logic state-distortion pattern conversion table defining the distortion patterns of the input waveforms at the first net in correspondence with logic states of cell instances and load capacitances driven by the plurality of cell instances, respectively; and
the waveform selecting step includes selecting the distortion pattern of the input waveform at the first net from the load capacitance basis logic state-distortion pattern conversion table in the library, according to the logic state of the cell instance determined in the logic state determination step and the load capacitance driven by the cell instance.

24. The delay simulation method according to claim 22, wherein
the first net is connected with a plurality of cell instances;
the logic state-distortion pattern conversion table defines the distortion patterns of the input waveforms at the first net in correspondence with combinations of logic states of the plurality of cell instances;
the waveform selecting step includes selecting the distortion pattern of the input waveform at the first net from the logic state-distortion pattern conversion table in the library, according to a combination of logic states of the plurality of cell instances determined in the logic state determination step.

25. The delay simulation method according to claim 23, wherein
the first net is connected with a plurality of cell instances;
the library includes a load capacitance basis logic state-distortion pattern conversion table defining distortion patterns of input waveforms at the first net in correspondence with combinations of logic states of the plurality of cell instances and a plurality of load capacitances driven by the plurality of cell instances, respectively; and
the waveform selecting step includes selecting the distortion pattern of the input waveform at the first net from the load capacitance basis logic state-distortion pattern conversion table in the library, according to a combination of logic states of the plurality of cell instances determined in the logic state determination step, and a combination of the plurality of load capacitances driven by the plurality of cell instances.

26. The delay simulation method according to claim 15, wherein
the simulation step includes obtaining, as the slope of the input waveform, a slope of a portion of a waveform input to the cell, the portion being an initial portion in a period of transition from one logic level to the other logic level.

27. A PLD mapping method comprising:
calculating delay using the delay simulation method as recited in claim 15;
performing mapping of a logic circuit to a PLD circuit based on a result of calculation of the delay;
and outputting resulting mapping information to the PLD circuit.
